(19) United States
(12) Patent Application Publication
(10) Pub. No.: US 2023/0337366 A1
(43) Pub. Date: Oct. 19, 2023

(54) CIRCUIT BOARD AND MANUFACTURING METHOD THEREOF

(71) Applicant: LG INNOTEK CO., LTD., Seoul (KR)

(72) Inventor: Ji Myoung LEE, Seoul (KR)

(73) Assignee: LG INNOTEK CO., LTD., Seoul (KR)

(21) Appl. No.: 18/025,535

(22) PCT Filed: Sep. 10, 2021
(86) PCT No.: PCT/KR2021/012329

§ 371 Date: Mar. 9, 2023

(30) Foreign Application Priority Data
Sep. 10, 2020 (KR) 10-2020-0116192

(51) Int. Cl. H05K 3/06; H05K 3/28

(52) U.S. Cl. CPC H05K 3/064; H05K 3/067; H05K 3/28; H05K 1/0306

(57) ABSTRACT

A circuit board according to an embodiment includes an insulating layer; a protective layer disposed on the insulating layer and including an opening; and a circuit pattern disposed on an insulating layer vertically overlapping the opening of the protective layer, wherein the circuit pattern includes: a first metal layer disposed on an upper surface of the insulating layer vertically overlapping the opening of the protective layer; a second metal layer disposed on the first metal layer; and a third metal layer disposed on the second metal layer, wherein the second metal layer includes: a first portion disposed between an upper surface of the first metal layer and a lower surface of the third metal layer; and a second portion disposed between an inner wall of the opening of the protective layer and a side surface of the third metal layer.

### TECHNICAL FIELD

An embodiment relates to a circuit board and a manufacturing method thereof.

### BACKGROUND ART

Electronic components are being miniaturized, lightweight, and integrated, and accordingly, a line width of circuit is miniaturized. In particular, design rules of semiconductor chips are being integrated on a nanometer scale, and accordingly, a circuit line width of a package substrate or a circuit board on which semiconductor chips are mounted is miniaturized to several micrometers or less.

Various methods have been proposed in order to increase the degree of circuit integration of the printed circuit board, that is, to reduce the circuit line width. For the purpose of preventing loss of the circuit line width in an etching step for forming a pattern after copper plating, a semi-additive process (SAP) method and a modified semi-additive process (MSAP) have been proposed.

Then, an embedded trace substrate (hereinafter referred to as “ETS”) method for embedding a copper foil in an insulating layer in order to implement a fine circuit pattern has been used in the industry. In the ETS method, instead of forming a copper foil circuit on a surface of the insulating layer, the copper foil circuit is manufactured in an embedded form in the insulating layer, and thus there is no circuit loss due to etching and it is advantageous for making the circuit pitch fine.

Meanwhile, recently, efforts have been made to develop an improved 5G (5th generation) communication system or a pre-5G communication system in order to meet a demand for wireless data traffic. Here, the 5G communication system uses ultra-high frequency (mmWave) bands (sub 6 GHz, 28 GHz, 38 GHz, or higher frequencies) to achieve high data transfer rates.

In addition, in order to reduce a path loss of radio waves and increase a transmission distance of radio waves in the ultra-high frequency band, in the 5G communication system, integration technologies such as beamforming, massive multi-input multi-output (massive MIMO), and array antennas have been developed. Considering that it may be composed of hundreds of active antennas of wavelengths in the frequency bands, an antenna system becomes large relatively.

Since such an antenna and AP module are patterned or mounted on the printed circuit board, low loss on the printed circuit board is very important. This means that several substrates constituting the active antenna system, that is, an antenna substrate, an antenna power feeding substrate, a transceiver substrate, and a baseband substrate, should be integrated into one compact unit.

In addition, the circuit board applied to the 5G communication system as described above is manufactured in a trend of light, thin and compact, and accordingly, the circuit pattern is becoming gradually finer. However, a conventional circuit board has a problem in that a process of forming the circuit pattern is complicated. Furthermore, a prior art has a problem in that the exposure and development process of the mask for forming the circuit pattern is complicated and difficult, and accordingly, there is a limit to miniaturization of the circuit pattern.

Accordingly, a new method for forming a circuit pattern of a circuit board is required.

### DISCLOSURE

### Technical Problem

An embodiment provides a circuit board having a new structure and a manufacturing method thereof.

In addition, the embodiment provides a circuit board including a circuit pattern formed using a back exposure method and a manufacturing method thereof.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises: an insulating layer; a protective layer disposed on the insulating layer and including an opening; and a circuit pattern disposed on an insulating layer vertically overlapping the opening of the protective layer, wherein the circuit pattern includes: a first metal layer disposed on an upper surface of the insulating layer vertically overlapping the opening of the protective layer; a second metal layer disposed on the first metal layer; and a third metal layer disposed on the second metal layer, wherein the second metal layer includes: a first portion disposed between an upper surface of the first metal layer and a lower surface of the third metal layer; and a second portion disposed between an inner wall of the opening of the protective layer and a side surface of the third metal layer.

In addition, a width of the opening of the protective layer is the same as a width of the circuit pattern.

In addition, the circuit board further comprises a primer layer disposed between the insulating layer and the first metal layer.

In addition, the first metal layer includes a metal material that blocks ultraviolet light.

In addition, an uppermost end of the second metal layer is positioned on a same plane as an uppermost end of the third metal layer.

In addition, the uppermost end of the second metal layer and the uppermost end of the third metal layer are positioned lower than an upper surface of the protective layer.

In addition, the insulating layer includes at least one of glass, light isotropic polycarbonate and light isotropic polymethyl methacrylate.

On the other hand, a method for manufacturing a circuit board comprises preparing an insulating layer including an upper surface and a lower surface, forming a first metal layer on the upper surface of the insulating layer, patterning the formed first metal layer to form a mask pattern; forming a protective layer covering the first metal layer on an upper surface of the insulating layer; exposing a first region of the protective layer by irradiating ultraviolet light under a lower surface of the insulating layer; forming an opening vertically overlapping an upper surface of the first metal layer in the protective layer by removing a second region except for the exposed first region, forming a second metal layer on an inner wall of the opening of the protective layer and the mask pattern of the first metal layer; and forming a third metal layer on the second metal layer, wherein the insulating layer includes a light-transmitting material that transmits ultraviolet light, and wherein the second region of the protective layer is a region vertically overlapping the mask pattern of the first metal layer.

In addition, the forming the opening includes forming the opening having the same width as the mask pattern of the first metal layer.

In addition, the second metal layer includes: a first portion disposed between an upper surface of the first metal layer and a lower surface of the third metal layer; and a second portion disposed between an inner wall of the opening of the protective layer and a side surface of the third metal layer.

### Advantageous Effects

In the embodiment, a circuit board is formed by applying a back exposure method. To this end, the circuit board of the embodiment includes a primer layer and a first metal layer corresponding to a mask layer for back exposure. In this case, the first metal layer is substantially used as a mask layer for exposure and development of a protective layer, and constitutes a part of a final circuit pattern. That is, the embodiment allows use of a part of the circuit pattern as a mask for exposure and development of the protective layer, and accordingly, a process of forming and removing a separate mask layer can be omitted. In addition, the embodiment allows the first metal layer used as the mask layer to have a thickness of 1 μm or less, so that it is possible to miniaturize the first metal layer. In addition, the embodiment allows the miniaturization of the first metal layer used as the mask layer, so that it is possible to miniaturize the opening formed in the protective layer, and furthermore, it is possible to miniaturize the second metal layer and the third metal layer disposed in the opening. Accordingly, the embodiment is advantageous in miniaturization of the circuit pattern compared to the comparative example.

In addition, the embodiment forms an opening by exposing and developing the protective layer using the first metal layer. In addition, the second metal layer and the third metal layer of the circuit pattern are formed in the opening of the formed protective layer. In other words, upper surfaces of the second metal layer and the third metal layer may be an uppermost surface of a circuit pattern exposed through the opening of the protective layer. In this case, the second metal layer and the third metal layer of the embodiment are formed to fill the opening after the opening of the protective layer is formed. Accordingly, the embodiment can prevent the protective layer from remaining in the second metal layer and the third metal layer, so that a process of removing remnants of the protective layer remaining on the surface of the circuit pattern can be omitted, thereby improving product reliability.

### DESCRIPTION OF DRAWINGS

FIG. 1 is a view showing a circuit board according to an embodiment.

FIGS. 2 to 11 are views showing a manufacturing method of a circuit board according to an embodiment in order of processes.

### MODES OF THE INVENTION

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, it will be understood that there are no intervening elements present.

As used herein, a singular expression includes a plural expression, unless the context clearly indicates otherwise.

It will be understood that the terms “comprise”, “include”, or “have” specify the presence of stated features, integers, steps, operations, elements, components and/or groups thereof disclosed in the present specification, but do not preclude the possibility of the presence or addition of one or more other features, integers, steps, operations, elements, components, and/or groups thereof.

Hereinafter, embodiments of the present invention will be described in detail with reference to the accompanying drawings.

The embodiment provides a manufacturing method differentiated from a conventional circuit board manufacturing method, and thus provides a structure different from that of the conventional circuit board. Accordingly, the embodiment allows miniaturization of the circuit pattern included in the circuit board, thereby enhancing its physical strength.

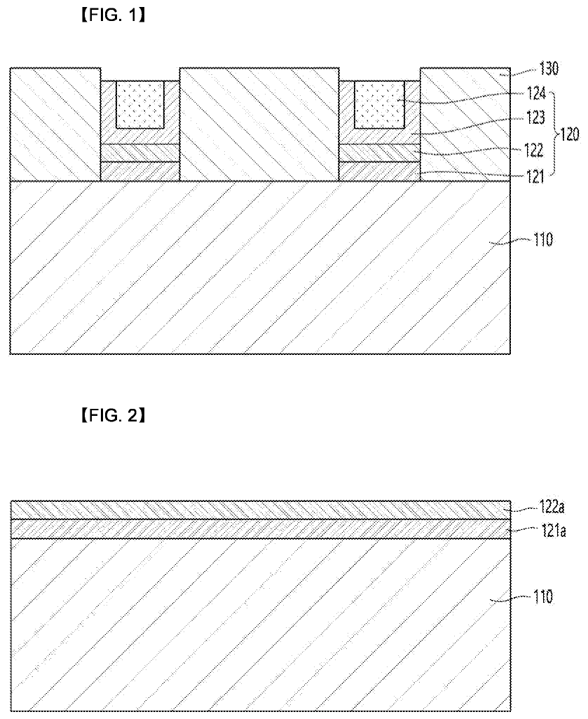

FIG. 1 is a view showing a circuit board according to an embodiment.

Referring to FIG. 1, the circuit board includes an insulating layer 110, a circuit pattern 120 and a protective layer 130. The circuit pattern 120 of the embodiment may have a multi-layer structure. In this case, some of the plurality of layers constituting the circuit pattern 120 may be a mask pattern. That is, the embodiment uses a part of the circuit pattern 120 so that it can be used as a mask pattern for ultraviolet (UV) exposure provided from a lower surface of the insulating layer 110. This will be described in detail.

The insulating layer 110 may refer to any one insulating layer among a plurality of insulating layers constituting the circuit board. That is, although the circuit board is illustrated as having a single-layer structure based on the insulating layer in the drawings, it is not limited thereto. For example, the circuit board may include two or more insulating layers, and the insulating layer 110 in FIG. 1 may mean any one of the two or more insulating layers.

The insulating layer 110 may include a material having light transmission. For example, the insulating layer 110 may be formed of glass or a flexible material. The flexible material may be plastic and may be formed of a material having excellent heat resistance and durability.

For example, the insulating layer 110 may include glass or plastic having light transmission. For example, the insulating layer 110 may include may be formed of a material such as photoisotropic polycarbonate (PC) or photoisotropic polymethylmethacrylate (PMMA), polyethersulphone (PES), polyacrylate (PAR), polyetherimide (PEI), polyethylenenapthalate (PET), or polyethylene terephthalate (PET).

However, the material of the insulating layer 110 is not limited to the above materials. For example, the insulating layer 110 may be made of a material having insulating properties while being able to pass UV light provided from one surface thereof to the other surface.

A circuit pattern 120 is disposed on one surface of the insulating layer 110. The circuit pattern 120 may have a multi-layer structure.

For example, the circuit pattern 120 may include a mask pattern for back exposure and a wiring pattern disposed on the mask pattern. That is, in the embodiment, the circuit pattern 120 is formed through back exposure. To this end, in the embodiment, a part of the circuit patterns 120 include a mask pattern for the back exposure.

Specifically, the circuit pattern 120 of the embodiment may include a primer layer 121 and a first metal layer 122.

The primer layer 121 may be disposed on the insulating layer 110. The primer layer 121 enables the formation of the first metal layer 122 on the insulating layer 110 according to a type of material constituting the insulating layer 110.

For example, when the insulating layer 110 is a glass substrate and a copper plating layer is directly formed on the glass substrate, adhesion between the glass substrate and the copper plating layer is low, and thus, a problem may occur in peel strength between the glass substrate and the copper plating layer.

Accordingly, in the embodiment, the primer layer 121 is selectively formed on the insulating layer 110. For example, when the insulating layer 110 includes light-transmitting plastic and a copper plating layer can be directly formed on the insulating layer 110, the primer layer 121 may be omitted.

For example, the primer layer 121 may be a primer layer for forming the first metal layer 122. For example, the primer layer 121 may be a metal sputter layer. Preferably, the primer layer 121 may be an organic primer layer for improving adhesion between the insulating layer 110 and the first metal layer 122.

A first metal layer 122 may be formed on the primer layer 121.

The first metal layer 122 may be a metal layer formed by sputtering. For example, the first metal layer 122 may include copper. However, the embodiment is not limited thereto, and any material that blocks ultraviolet light may be formed as the first metal layer 122. However, the first metal layer 122 of the embodiment constitutes a part of the circuit pattern 120, and therefore, the first metal layer 122 is formed of a conductive metal material while blocking ultraviolet light. For example, the first metal layer 122 is a part of a wiring that transmits an electrical signal, and may be formed of a metal material that has high electrical conductivity and can block ultraviolet light. For example, the first metal layer 122 may be formed of at least one metal material selected from gold (Au), silver (Ag), platinum (Pt), titanium (Ti), tin (Sn), copper (Cu), and zinc (Zn). Preferably, the first metal layer 122 may be formed of copper (Cu), which has high electrical conductivity and is relatively inexpensive.

Meanwhile, the primer layer 121 has a thickness in the range of 0.1 μm to 1.0 μm, and may be selectively formed on the insulating layer 110. That is, the primer layer 121 is not an essential component, and when it is difficult to directly form the first metal layer 122 on the insulating layer 110, it may be selectively disposed between the insulating layer 110 and the first metal layer 122.

In addition, the first metal layer 122 has a thickness ranging from 0.5 μm to 1.0 μm and may be selectively disposed on the insulating layer 110 or the primer layer 121.

The primer layer 121 and the first metal layer 122 are mask layers for exposing and developing the protective layer 130, it may be preferentially formed before the protective layer 130 is formed.

In the embodiment, the protective layer 130 can be back exposed by using the first metal layer 122 having a thickness of 1.0 μm or less as described above. In addition, a wiring pattern may be formed in an opening of the protective layer 130 after back exposure of the protective layer 130 is performed. Accordingly, the embodiment proceeds a process of forming the circuit pattern 120 using the first metal layer 122 having a thickness of 1.0 μm or less as described above, which is advantageous in forming a fine pattern.

Here, the back exposure is not irradiating light for exposure of the protective layer on the upper surface of the protective layer 130, and may mean irradiating light for exposure of the protective layer under a lower surface of the insulating layer 110 disposed below the protective layer 130.

A second metal layer 123 and a third metal layer 124 are disposed on the first metal layer 122.

The second metal layer 123 is disposed on the first metal layer 122.

The second metal layer 123 may be a seed layer for forming the third metal layer 124. For example, the second metal layer 123 may be a chemical copper plating layer. For example, the second metal layer 123 may be an electroless plating layer formed to electrolytically plate the third metal layer 124.

The second metal layer 123 may be disposed on the first metal layer 122 while surrounding the third metal layer 124.

For example, the second metal layer 123 may be disposed on the first metal layer 122 in a ‘U’ shape including an opening in a center. In addition, the third metal layer 124 may be disposed within the opening of the second metal layer 123.

Accordingly, the third metal layer 124 may be surrounded by the second metal layer 123. Preferably, lower and side surfaces of the third metal layer 124 may be surrounded by the second metal layer 123.

For example, the second metal layer 123 may include a first portion disposed on the first metal layer 122 and having an upper surface directly contacting a lower surface of the third metal layer 124.

In addition, the second metal layer 123 may include a second portion that protrudes from an edge of the first metal layer 122 to an upper region and thus directly contacts the side surface of the third metal layer 124.

The second metal layer 123 may be disposed on the first metal layer 122 to have a thickness ranging from 0.1 μm to 5.0 μm.

The third metal layer 124 may be an electrolytic plating layer formed by electroplating the second metal layer 123 as a seed layer. The third metal layer 124 may have a thickness of 15 μm to 30 μm.

In an embodiment, an uppermost surface of the second metal layer 123 and an uppermost surface of the third metal layer 124 may be positioned on the same plane. That is, the embodiment proceeds with a process of simultaneously etching the second metal layer and the third metal layer after forming the second metal layer 123 and the third metal layer 124. Accordingly, the uppermost surface of the second metal layer 123 and the uppermost surface of the third metal layer 124 may be positioned on the same plane.

Meanwhile, a protective layer 130 including an opening exposing the circuit pattern 120 may be disposed on the insulating layer 110. The protective layer 130 may be a solder resist (SR), but is not limited thereto. For example, the protective layer 130 may be a resin capable of exposure and development by UV light while protecting the surface of the insulating layer 110.

The opening of the protective layer 130 may be formed through exposure and development by UV light provided from the lower surface of the insulating layer 110 while using the primer layer 121 and the first metal layer 122 as a mask.

Accordingly, the protective layer 130 may be disposed in direct contact with side surfaces of the primer layer 121, the first metal layer 122, and the second metal layer 123. However, the third metal layer 124 is surrounded by the second metal layer 123, and thus may not contact the protective layer 130.

Meanwhile, the protective layer 130 of the embodiment may be formed after the primer layer 121 and the first metal layer 122 are formed, and may be formed before the second metal layer 123 and the third metal layer 124 are formed.

Accordingly, the remnants of the protective layer 130 may not remain on the surfaces of the second metal layer 123 and the third metal layer 124.

Meanwhile, a width of the opening of the protective layer 130 of the embodiment may correspond to a width of the circuit pattern 120.

For example, the comparative example forms a protective layer on the circuit pattern after all layers of the circuit pattern are formed, and forms an opening vertically overlapping the upper surface of the circuit pattern in the protective layer. Accordingly, it is difficult to form the opening of the protective layer substantially equal to the width of the circuit pattern. For example, the protective layer of the comparative example has a SMD (Solder Mask Defined) structure in which the width of the opening is smaller than the width of the circuit pattern or a Non-Solder Mask Defined (NSMD) structure in which the width of the opening is greater than the width of the circuit pattern.

In contrast, the embodiment can form an opening having a width corresponding to the circuit pattern in the protective layer using a back exposure method, and accordingly, the circuit pattern 120 may have the same width as the opening of the protective layer 130.

For example, a solder resist in the circuit board of a comparative example is formed on the circuit pattern to cover the circuit pattern after all the circuit patterns are formed. In addition, the comparative example proceeds with a process of forming an opening exposing the surface of the circuit pattern by exposing and developing the solder resist is performed. However, the comparative example has a problem that the remains of the solder resist remain on the surface of the circuit pattern after the exposure and development of the solder resist proceeds, and therefore, an additional process to remove debris must be performed.

In contrast, the embodiment forms an opening in the protective layer 130 using the first metal layer 122, and accordingly, the embodiment forms the second metal layer 123 and the third metal layer within the opening of the protective layer 130. In this case, the second metal layer 123 and the third metal layer 124 are formed to fill the opening of the protective layer 130 after the opening of the protective layer is formed. Accordingly, the embodiment can prevent the protective layer 130 from remaining on the surfaces of the second metal layer 123 and the third metal layer 124, and accordingly, it is possible to simplify the manufacturing process and improve product reliability.

Meanwhile, the upper surface of the protective layer 130 may be positioned higher than the uppermost surface of the second metal layer 123 or the uppermost surface of the third metal layer 124. In other words, the upper surface of the circuit pattern 120 may be positioned lower than the upper surface of the protective layer 130. For example, the circuit pattern 120 may have a recessed structure in the opening of the protective layer 130. Accordingly, the circuit pattern 120 of the embodiment may have a structure recessed in the protective layer 130, so that the protective layer 130 can function as a dam to confine the adhesive member when an adhesive member such as a solder ball is disposed on the circuit pattern 120, and accordingly, placement reliability of the adhesive member may be improved.

In the embodiment, a circuit board is formed by applying a back exposure method. To this end, the circuit board of the embodiment includes a primer layer and a first metal layer corresponding to a mask layer for back exposure. In this case, the first metal layer is substantially used as a mask layer for exposure and development of a protective layer, and constitutes a part of a final circuit pattern. That is, the embodiment allows use of a part of the circuit pattern as a mask for exposure and development of the protective layer, and accordingly, a process of forming and removing a separate mask layer can be omitted. In addition, the embodiment allows the first metal layer used as the mask layer to have a thickness of 1 μm or less, so that it is possible to miniaturize the first metal layer. In addition, the embodiment allows the miniaturization of the first metal layer used as the mask layer, so that it is possible to miniaturize the opening formed in the protective layer, and furthermore, it is possible to miniaturize the second metal layer and the third metal layer disposed in the opening. Accordingly, the embodiment is advantageous in miniaturization of the circuit pattern compared to the comparative example.

In addition, the embodiment forms an opening by exposing and developing the protective layer using the first metal layer. In addition, the second metal layer and the third metal layer of the circuit pattern are formed in the opening of the formed protective layer. In other words, upper surfaces of the second metal layer and the third metal layer may be an uppermost surface of a circuit pattern exposed through the opening of the protective layer. In this case, the second metal layer and the third metal layer of the embodiment are formed to fill the opening after the opening of the protective layer is formed. Accordingly, the embodiment can prevent the protective layer from remaining in the second metal layer and the third metal layer, so that a process of removing remnants of the protective layer remaining on the surface of the circuit pattern can be omitted, thereby improving product reliability.

Hereinafter, a method of manufacturing a circuit board according to the embodiment shown in FIG. 1 will be described in detail with reference to the accompanying drawings.

FIGS. 2 to 11 are views showing a manufacturing method of a circuit board according to an embodiment in process order.

Firstly, referring to FIG. 2, the embodiment prepares an insulating layer 110, which is a basic member for manufacturing a circuit board.

In this case, the insulating layer 110 may include a material having light transmission. For example, the insulating layer 110 may be formed of glass or a flexible material. The flexible material may be plastic and may be formed of a material having excellent heat resistance and durability. For example, the insulating layer 110 may include glass or plastic having light transmission. For example, the insulating layer 110 may include may be formed of a material such as photoisotropic polycarbonate (PC) or photoisotropic polymethylmethacrylate (PMMA), polyethersulphone (PES), polyacrylate (PAR), polyetherimide (PEI), polyethylenenapthalate (PET), or polyethylene terephthalate (PET). However, the material of the insulating layer 110 is not limited to the above materials. For example, the insulating layer 110 may be made of a material having insulating properties while being able to pass UV light provided from one surface thereof to the other surface.

Next, the embodiment proceeds with a process of sequentially forming a primer layer 121a and a first metal layer 122a on the insulating layer 110.

The primer layer 121a may be sputtered or coated on the insulating layer 110. The primer layer 121a may be selectively formed on the insulating layer 110 according to a type of material constituting the insulating layer 110.

For example, when the insulating layer 110 is a glass substrate and a copper plating layer corresponding to a first metal layer 112a is directly formed on the glass substrate, adhesion between the glass substrate and the copper plating layer is low, and thus, a problem may occur in peel strength between the glass substrate and the copper plating layer.

Accordingly, in the embodiment, the primer layer 121a is selectively formed on the insulating layer 110. For example, when the insulating layer 110 includes light-transmitting plastic and a copper plating layer can be directly formed on the insulating layer 110, the primer layer 121a may be omitted.

For example, the primer layer 121a may be a primer layer for forming the first metal layer 122a. For example, the primer layer 121a may be a metal sputter layer. Preferably, the primer layer 121a may be an organic primer layer for improving adhesion between the insulating layer 110 and the first metal layer 122a.

The primer layer 121a has a thickness in a range of 0.1 μm to 1.0 μm, and may be selectively formed on the insulating layer 110. That is, the primer layer 121a is not an essential component, and when it is difficult to directly form the first metal layer 122a on the insulating layer 110, it may be selectively disposed between the insulating layer 110 and the first metal layer 122a.

Next, when the primer layer 121a is formed, the embodiment may proceed with a process of forming the first metal layer 122a on the primer layer 121a.

The first metal layer 122a may be a metal layer formed by sputtering. For example, the first metal layer 122a may include copper. However, the embodiment is not limited thereto, and any material that blocks ultraviolet light may be formed as the first metal layer 122a. However, the first metal layer 122a of the embodiment constitutes a part of the circuit pattern 120, and therefore, the first metal layer 122a is formed of a conductive metal material while blocking ultraviolet light. For example, the first metal layer 122a is a part of a wiring that transmits an electrical signal, and may be formed of a metal material that has high electrical conductivity and can block ultraviolet light. For example, the first metal layer 122a may be formed of at least one metal material selected from gold (Au), silver (Ag), platinum (Pt), titanium (Ti), tin (Sn), copper (Cu), and zinc (Zn). Preferably, the first metal layer 122a may be formed of copper (Cu), which has high electrical conductivity and is relatively inexpensive.

The first metal layer 122 has a thickness ranging from 0.5 μm to 1.0 μm and may be selectively disposed on the insulating layer 110 or the primer layer 121.

The primer layer 121a and the first metal layer 122a are mask layers for exposing and developing the protective layer 130, and it may be preferentially formed before the protective layer 130 is formed.

Meanwhile, reference numerals “121a” and “122a” mean a layer before etching, and “121” and “122” hereinafter may mean a layer after etching.

Next, referring to FIG. 3, the embodiment may proceed with a process of forming a dry film resist (DFR) on the first metal layer 122.

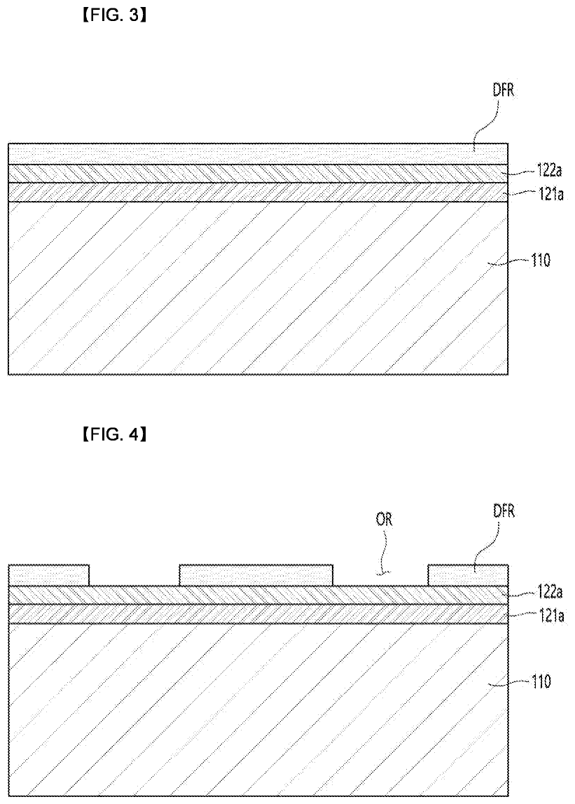

Next, referring to FIG. 4, the embodiment may proceed with a process of forming an open region OR exposing a part of the upper surfaces of the primer layer 121a and the first metal layer 122a by exposing and developing the dry film resist (DFR).

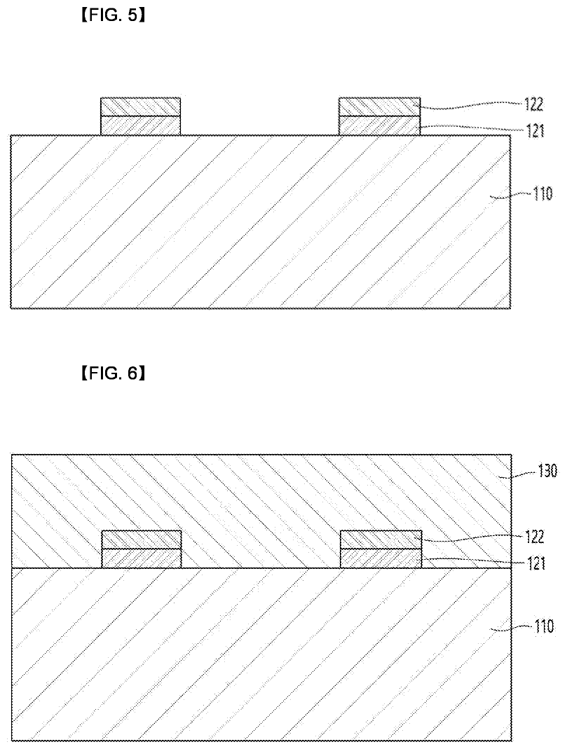

Next, referring to FIG. 5, the embodiment may proceed with a process of etching and removing the primer layer 121a and the first metal layer 122a corresponding to the open region (OR) of the dry film resist (DFR).

Accordingly, in the embodiment, it is possible to form a mask layer for exposure and development of the protective layer 130 on the insulating layer 110. In addition, a portion of the mask layer for exposure and development of the protective layer 130 constitutes a portion of the circuit pattern 120 later.

Next, a protective layer 130 having a predetermined height may be formed on the insulating layer 110 as shown in FIG. 6. In this case, the protective layer 130 may be disposed while covering the primer layer 121 and the first metal layer 122. For example, an upper surface of the protective layer 130 may be positioned higher than an upper surface of the first metal layer 122. Accordingly, the primer layer 121 and the first metal layer 122 may be buried in the protective layer 130.

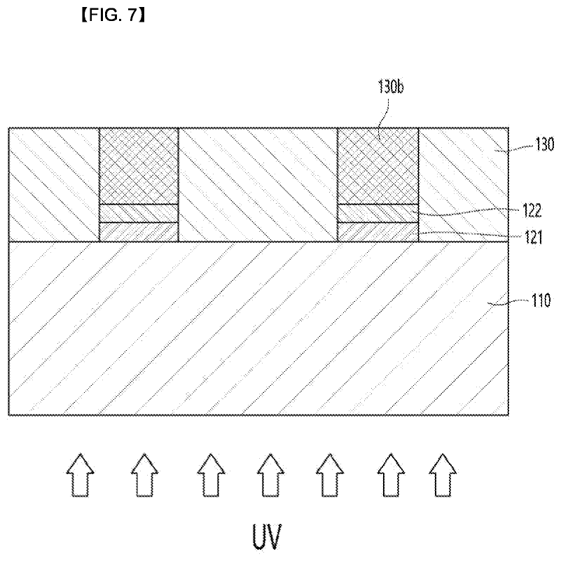

Next, the embodiment may proceed with back exposure as shown in FIG. 7. That is, a general manufacturing process of a circuit board includes exposure in an upward direction of the mask after the mask is formed.

In contrast, the embodiment proceeds with a process of exposing the protective layer 130 in a lower direction. Specifically, the primer layer 121, the first metal layer 122, and the protective layer 130 may be formed on the first surface of the insulating layer 110. In addition, the exposure may be performed on a second surface opposite to the first surface of the insulating layer 110.

That is, the embodiment may irradiate ultraviolet light on the second surface of the insulating layer 110. In this case, the irradiated ultraviolet light may pass through the insulating layer 110 and be transmitted to the protective layer 130 disposed on the first surface of the insulating layer 110.

In this case, the primer layer 121 and the first metal layer 122 are formed on the first surface of the insulating layer 110.

Accordingly, a region 130a of the protective layer 130 that does not overlap with the primer layer 121 and the first metal layer 122 in the vertical direction may be exposed to light. In addition, ultraviolet light is not transmitted to a region 130b of the protective layer 130 overlapping the primer layer 121 and the first metal layer 122 in a vertical direction by the first metal layer 122, and accordingly, it may not proceed with exposure.

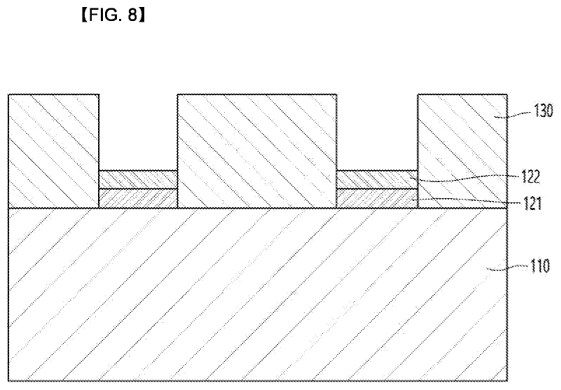

Next, the embodiment, may proceed with a process of developing by removing an unexposed region 130b of the protective layer 130 as shown in FIG. 8. In addition, the embodiment may proceed with a process of exposing the upper surface of the first metal layer 122 by removing the unexposed region 130b. That is, the embodiment may proceed with a process of forming an opening exposing the surface of the first metal layer 122 in the protective layer 130 by removing the unexposed region 130b. In this case, the embodiment proceeds with a de-smear process after the opening is formed in the protective layer 130, Accordingly, the embodiment may proceed with a process of removing a portion of the protective layer 130 remaining on the surface of the first metal layer 122. However, the process of removing the remnants of the protective layer 130 may be omitted, and thus at least a portion of the protective layer 130 may exist on the upper surface of the first metal layer 122. In this case, the first metal layer 122 does not perform a signal transmission function, which is the main function of the circuit pattern 120, but serves as a mask for back exposure. Accordingly, even if a part of the protective layer 130 remains on the upper surface of the first metal layer 122, a reliability problem does not occur.

Next, the embodiment may proceed with a process of forming the second metal layer 123 on an upper surface of the protective layer 130, an inner wall of the opening of the protective layer 130, and an upper surface of the first metal layer 122 as shown in FIG. 9.

The second metal layer 123 may be a seed layer for forming the third metal layer 124. For example, the second metal layer 123 may be a chemical copper plating layer. For example, the second metal layer 123 may be an electroless plating layer formed to electrolytically plate the third metal layer 124.

For example, the second metal layer 123 may be disposed on the first metal layer 122 in a ‘U’ shape including an opening in a center. In addition, the third metal layer 124 may be disposed within the opening of the second metal layer 123.

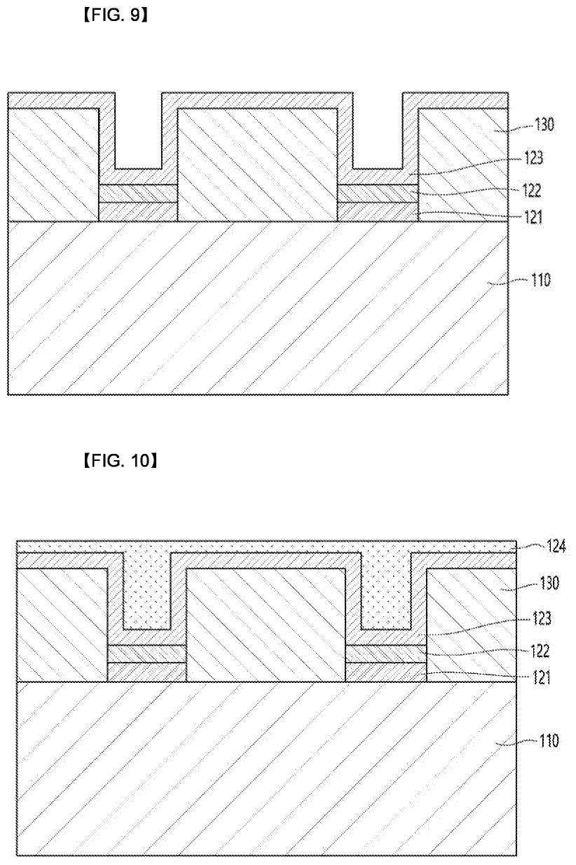

Next, the embodiment may proceed with a process of forming the third metal layer 124 filling the opening of the protective layer 130 on the second metal layer 123 as shown in FIG. 10. In this case, the third metal layer 124 may be an electrolytic plating layer formed by electroplating the second metal layer 123 as a seed layer.

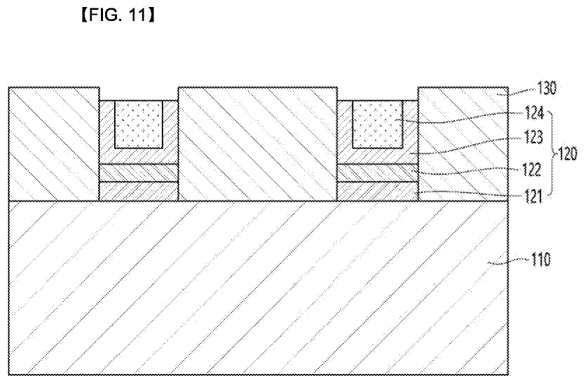

Next, the embodiment may proceed with a process of removing the second metal layer 123 and the third metal layer 124 disposed on the surface of the protective layer 130 as shown in FIG. 11. In addition, when removing the second metal layer 123 and the third metal layer 124 disposed on the surface of the protective layer 130, the embodiment may proceed with a process of removing a part of the second metal layer 123 and the third metal layer 124 disposed in the opening of the protective layer 130. Accordingly, the upper surfaces of the second metal layer 123 and the third metal layer 124 of the embodiment may be positioned lower than the upper surface of the protective layer 130. For example, the second metal layer 123 and the third metal layer 124 may have a recessed structure in the opening of the protective layer 130.

Accordingly, the third metal layer 124 may be surrounded by the second metal layer 123. Preferably, lower and side surfaces of the third metal layer 124 may be surrounded by the second metal layer 123.

For example, the second metal layer 123 may include a first portion disposed on the first metal layer 122 and having an upper surface directly contacting a lower surface of the third metal layer 124.

In addition, the second metal layer 123 may include a second portion that protrudes from an edge of the first metal layer 122 to an upper region and thus directly contacts the side surface of the third metal layer 124.

The second metal layer 123 may be disposed on the first metal layer 122 to have a thickness ranging from 0.1 μm to 5.0 μm.

The third metal layer 124 may be an electrolytic plating layer formed by electroplating the second metal layer 123 as a seed layer. The third metal layer 124 may have a thickness of 15 μm to 30 μm.

In an embodiment, an uppermost surface of the second metal layer 123 and an uppermost surface of the third metal layer 124 may be positioned on the same plane. That is, the embodiment proceeds with a process of simultaneously etching the second metal layer and the third metal layer after forming the second metal layer 123 and the third metal layer 124, and accordingly, the uppermost surface of the second metal layer 123 and the uppermost surface of the third metal layer 124 may be positioned on the same plane.

In the embodiment, a circuit board is formed by applying a back exposure method. To this end, the circuit board of the embodiment includes a primer layer and a first metal layer corresponding to a mask layer for back exposure. In this case, the first metal layer is substantially used as a mask layer for exposure and development of a protective layer, and constitutes a part of a final circuit pattern. That is, the embodiment allows use of a part of the circuit pattern as a mask for exposure and development of the protective layer, and accordingly, a process of forming and removing a separate mask layer can be omitted. In addition, the embodiment allows the first metal layer used as the mask layer to have a thickness of 1 μm or less, so that it is possible to miniaturize the first metal layer. In addition, the embodiment allows the miniaturization of the first metal layer used as the mask layer, so that it is possible to miniaturize the opening formed in the protective layer, and furthermore, it is possible to miniaturize the second metal layer and the third metal layer disposed in the opening. Accordingly, the embodiment is advantageous in miniaturization of the circuit pattern compared to the comparative example.

In addition, the embodiment forms an opening by exposing and developing the protective layer using the first metal layer. In addition, the second metal layer and the third metal layer of the circuit pattern are formed in the opening of the formed protective layer. In other words, upper surfaces of the second metal layer and the third metal layer may be an uppermost surface of a circuit pattern exposed through the opening of the protective layer. In this case, the second metal layer and the third metal layer of the embodiment are formed to fill the opening after the opening of the protective layer is formed. Accordingly, the embodiment can prevent the protective layer from remaining in the second metal layer and the third metal layer, so that a process of removing remnants of the protective layer remaining on the surface of the circuit pattern can be omitted, thereby improving product reliability.

The characteristics, structures, effects, and the like described in the above-described embodiments are included in at least one embodiment, but are not limited to only one embodiment. Furthermore, the characteristic, structure, and effect illustrated in each embodiment may be combined or modified for other embodiments by a person skilled in the art. Therefore, it should be construed that contents related to such combination and modification are included in the scope of the embodiment.

Embodiments are mostly described above, but the embodiments are merely examples and do not limit the embodiments, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the embodiment defined in the following claims.

1-10. (canceled)

11. A circuit board comprising:
an insulation layer;
a circuit pattern disposed on the insulating layer; and
a protective layer disposed on the insulating layer and including an opening overlapping the circuit pattern in a vertical direction;
wherein an upper surface of the circuit pattern is positioned lower than an upper surface of the protective layer, and
wherein a width of the circuit pattern is same as a width of the opening.

12. The circuit board of claim 11, wherein the circuit pattern does not overlap the protective layer in the vertical direction.

13. The circuit board of claim 11, wherein the circuit pattern includes a first metal layer disposed on the insulating layer; and
wherein a width of the first metal layer is same as the width of the opening.

14. The circuit board of claim 13, wherein the circuit pattern further includes:
a second metal layer disposed on the first metal layer; and
a third metal layer disposed on the second metal layer; and
wherein the second metal layer is provided to surround a side surface and a lower surface of the third metal layer in the opening.

15. The circuit board of claim 14, wherein an uppermost end of the second metal layer and an uppermost end of the third metal layer are positioned on the same plane and lower than an upper surface of the protective layer.

16. The circuit board of claim 11, wherein the opening is a through hole passing through upper and lower surfaces of the protective layer.

17. The circuit board of claim 16, wherein the circuit pattern contacts an inner wall of the opening of the protective layer without contacting the upper and lower surfaces of the protective layer.

18. The circuit board of claim 13, wherein the first metal layer includes a metal material that blocks ultraviolet light.

19. The circuit board of claim 11, further comprising:
a primer layer disposed between the insulating layer and the circuit pattern.

20. The circuit board of claim 19, wherein a width of the primer layer is same as the width of the opening.

21. The circuit board of claim 19, wherein a width of the primer layer is same as the width of the circuit pattern.

22. The circuit board of claim 11, wherein the insulating layer includes a light-transmitting material.

23. The circuit board of claim 19, wherein a side surface of the primer layer and a side surface of the circuit pattern are disposed on the same vertical line.

24. The circuit board of claim 19, wherein the primer layer overlaps the protective layer in a horizontal direction without overlapping the protective layer in a vertical direction.

25. A method for manufacturing a circuit board, the method comprising:
preparing an insulating layer including an upper surface and a lower surface;
forming a first metal layer on the upper surface of the insulating layer;
patterning the formed first metal layer to form a mask pattern;
forming a protective layer covering the first metal layer on an upper surface of the insulating layer;
exposing a first region of the protective layer by irradiating ultraviolet light under a lower surface of the insulating layer;
forming an opening vertically overlapping an upper surface of the first metal layer in the protective layer by removing a second region except for the exposed first region;
forming a second metal layer on an inner wall of the opening of the protective layer and the mask pattern of the first metal layer; and
forming a third metal layer on the second metal layer,
wherein the insulating layer includes a light-transmitting material that transmits ultraviolet light; and
wherein the second region of the protective layer is a region vertically overlapping the mask pattern of the first metal layer.

26. The method of claim 25, wherein a width of the first metal layer is same as a width of the opening of the protective layer.

27. The method of claim 25, wherein an upper surface of the third metal layer is positioned lower than the upper surface of the protective layer.

28. The method of claim 25, further comprising:
forming a primer layer on the insulating layer before forming the first metal layer,
wherein the forming of the mask pattern includes forming a mask pattern by patterning the primer layer together with the first metal layer.

29. The method of claim 28, wherein the mask pattern includes a first layer corresponding to the first metal layer and a second layer corresponding to the primer layer, and
wherein a width of each of the first layer and the second layer is same as a width of the opening of the protective layer.

30. The method of claim 25, wherein the first metal layer includes a metal material that blocks ultraviolet light, and
wherein the insulating layer includes a light-transmitting material.
